(19) United States
(12) Patent Application Publication
(10) Pub. No.: US 2024/0250214 A1
(43) Pub. Date: Jul. 25, 2024

(54) GALLIUM NITRIDE-BASED SEMICONDUCTOR DEVICE ON AMORPHOUS SUBSTRATE

(71) Applicant: Japan Display Inc., Tokyo (JP)

(72) Inventors: Hiroumi KINJO, Tokyo (JP); Masumi NISHIMURA, Tokyo (JP); Hayata AOKI, Tokyo (JP)

(73) Assignee: Japan Display Inc., Tokyo (JP)

(21) Appl. No.: 18/589,784

(22) Filed: Feb. 28, 2024

Related U.S. Application Data
(63) Continuation of application No. PCT/JP2022/029875, filed on Aug. 4, 2022.

(30) Foreign Application Priority Data
Sep. 3, 2021 (JP) 2021-144296

(51) Int. Cl. H01L 33/36; H01L 33/06; H01L 33/16; H01L 33/32

(52) U.S. Cl. CPC H01L 33/36; H01L 33/06; H01L 33/16; H01L 33/32

(57) ABSTRACT

A gallium nitride-based semiconductor device includes an amorphous substrate, a conductive alignment layer on the amorphous substrate, a gallium nitride-based semiconductor layer on the conductive alignment layer, and an auxiliary electrode layer in contact with the conductive alignment layer. The auxiliary electrode layer is arranged around a periphery portion of the conductive alignment layer.

### CROSS-REFERENCE TO RELATED APPLICATIONS

This application is a Continuation of International Patent Application No. PCT/JP2022/029875, filed on Aug. 4, 2022, which claims the benefit of priority to Japanese Patent Application No. 2021-144296, filed on Sep. 3, 2021, the entire contents of which are incorporated herein by reference.

### FIELD

An embodiment of the present invention relates to a semiconductor device including a crystalline compound semiconductor layer on an amorphous substrate.

### BACKGROUND

A gallium nitride-based compound semiconductor light emitting diode formed by vapor phase growth of a gallium nitride-based compound semiconductor by a metal-organic compound vapor phase growth method (MOCVD) on a crystalline sapphire substrate is known. The gallium nitride-based compound semiconductor light-emitting diode on a crystalline sapphire substrate realizes blue light emission, has high conversion efficiency and long life, and is widely used in practical applications. However, since crystalline sapphire substrates are expensive and their area is not easy to increase, research has been underway to fabricate crystalline gallium nitride-based compound semiconductors on amorphous substrates.

When fabricating light-emitting devices using gallium nitride layers, it is convenient if the gallium nitride layers can be placed on top of the metal layer and the metal layer can be used as an electrode. However, it is difficult to use the metal layer on a base side of the gallium nitride layers as an electrode because of restrictions on the material and thickness of the metal layer. That is, when the light-emitting devices are formed on amorphous substrates, there is a concern that although the light is emitted brightly near the connection with the power supply line, the brightness decreases and becomes darker as the distance from the connection with the power supply increases.

### SUMMARY

A gallium nitride-based semiconductor device in an embodiment according to the present invention includes an amorphous substrate, a conductive alignment layer on the amorphous substrate, a gallium nitride-based semiconductor layer on the conductive alignment layer, and an auxiliary electrode layer in contact with the conductive alignment layer.

### BRIEF DESCRIPTION OF DRAWINGS

FIG. 1A is a structure in which an auxiliary electrode layer is arranged on an upper side of a conductive alignment layer in a gallium nitride-based semiconductor device according to an embodiment of the present invention.

FIG. 1B is a structure in which an auxiliary electrode layer is arranged on a lower side of a conductive alignment layer in a gallium nitride-based semiconductor device according to an embodiment of the present invention.

FIG. 2A is a plan view of a gallium nitride-based device according to an embodiment of the present invention.

FIG. 2B is a cross sectional view of a gallium nitride-based device according to an embodiment of the present invention.

FIG. 3A is a plan view of a gallium nitride-based device according to an embodiment of the present invention.

FIG. 3B is a cross sectional view of a gallium nitride-based device according to an embodiment of the present invention.

FIG. 4A is a plan view of a gallium nitride-based device according to an embodiment of the present invention.

FIG. 4B is a cross sectional view of a gallium nitride-based device according to an embodiment of the present invention.

FIG. 5A is a plan view of a gallium nitride-based device according to an embodiment of the present invention.

FIG. 5B is a cross sectional view of a gallium nitride-based device according to an embodiment of the present invention.

FIG. 6A is a plan view of a gallium nitride-based device according to an embodiment of the present invention.

FIG. 6B is a cross sectional view of a gallium nitride-based device according to an embodiment of the present invention.

FIG. 7A is a plan view of a gallium nitride-based device according to an embodiment of the present invention.

FIG. 7B is a cross sectional view of a gallium nitride-based device according to an embodiment of the present invention.

FIG. 8A is a plan view of a gallium nitride-based device according to an embodiment of the present invention.

FIG. 8B is a cross sectional view of a gallium nitride-based device according to an embodiment of the present invention.

FIG. 9A is a plan view of a gallium nitride-based device according to an embodiment of the present invention.

FIG. 9B is a cross sectional view of a gallium nitride-based device according to an embodiment of the present invention.

FIG. 10A is a plan view of a gallium nitride-based device according to an embodiment of the present invention.

FIG. 10B is a cross sectional view of a gallium nitride-based device according to an embodiment of the present invention.

FIG. 11A is a plan view of a gallium nitride-based device according to an embodiment of the present invention.

FIG. 11B is a cross sectional view of a gallium nitride-based device according to an embodiment of the present invention.

FIG. 12A is a plan view of a gallium nitride-based device according to an embodiment of the present invention.

FIG. 12B is a cross sectional view of a gallium nitride-based device according to an embodiment of the present invention.

FIG. 13 is a structure of a gallium nitride-based device according to an embodiment of the present invention.

FIG. 14 is a configuration of a light-emitting device according to an embodiment of the present invention.

### DESCRIPTION OF EMBODIMENTS

Hereinafter, embodiments of the present invention are described with reference to the drawings. However, the present invention can be implemented in many different aspects, and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by a, b, etc.) and a detailed description may be omitted as appropriate. The terms “first” and “second” appended to each element are a convenience terms used to distinguish them and have no further meaning except as otherwise explained.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

### First Embodiment

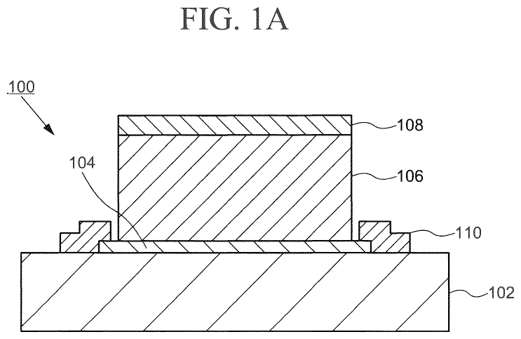

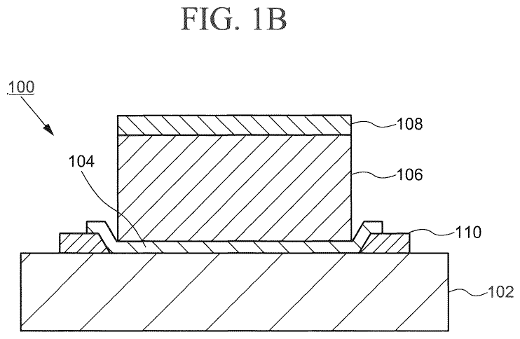

FIG. 1A and FIG. 1B show a cross-sectional structure of a gallium nitride-based semiconductor device 100 according to an embodiment of the present invention. As shown in FIG. 1A and FIG. 1B, the gallium nitride-based semiconductor device 100 has a structure in which a conductive alignment layer 104, a gallium nitride-based semiconductor layer 106, and an upper electrode layer 108 are arranged on an amorphous substrate 102. The gallium nitride-based semiconductor device 100 further includes an auxiliary electrode layer 110 that is in contact with the conductive alignment layer 104.

The conductive layer 104 and the upper electrode layer 108 are used as electrodes and the gallium nitride-based semiconductor layer 106 is used as a functional layer to express a predetermined function in the gallium nitride-based semiconductor device 100. The predetermined function varies depending on the structure of the device, for example, it may include functions such as light emission, amplification, switching, and the like.

As used herein, gallium nitride-based semiconductor devices shall refer to semiconductor devices having a gallium nitride layer formed on an amorphous substrate and configured to express a predetermined function. The gallium nitride-based semiconductor devices can include light-emitting devices such as light-emitting diodes and active devices such as transistors. The gallium nitride-based semiconductor layer refers to semiconductor layers including at least one gallium nitride layer, and may include a structure in which a plurality of gallium nitride layers of different conductive types is stacked.

Next, details of each part configuring the gallium nitride-based semiconductor device 100 shown in FIG. 1A and FIG. 1B will be described.

A glass substrate is used as the amorphous substrate 102. The glass substrate should have a low alkali component content, a low coefficient of thermal expansion, a high strain point, and a high surface flatness. Although alkali components are common components in ordinary glass, it is preferable for the glass substrate used in this embodiment to have 0.1% or less of alkali metals such as sodium. The glass substrate should have an expansion coefficient of less than 50×10⁻⁷/° C. and a strain point of 600° C. or higher. The glass substrate does not contain alkali components and has high heat resistance, which enables the deposition of a crystalline gallium nitride-based semiconductor layer by the sputtering method to form semiconductor devices, as described below.

However, the amorphous substrate 102 is not required to have heat resistance above 1000° C. like sapphire substrates. Rather, a glass substrate, such as those used in liquid crystal displays and organic electroluminescence (OLED) displays, can be used as the amorphous substrate 102 to fabricate gallium nitride-based semiconductor devices on a large-area glass substrate called a mother glass. A resin substrate such as polyimide, acrylic, siloxane, and fluoropolymer substrates may be used as the amorphous substrate 102.

Although not shown in FIG. 1A and FIG. 1B, an insulating layer may be deposited on the surface of the amorphous substrate 102. For example, a silicon nitride film, silicon oxide film, or aluminum oxide film may be used as the insulating layer. The insulating layer may have a structure in which a plurality of insulating films is stacked, for example, a silicon nitride film and a silicon oxide film may be stacked.

The conductive alignment layer 104 is arranged on the amorphous substrate 102. The conductive alignment layer 104 is a conductive film having crystalline properties. The crystals of the conductive alignment layer 104 are oriented, and the crystals should be oriented, for example, on the c-axis. The conductive alignment layer 104 should be crystalline with rotational symmetry, for example, its crystal surface should have 6-fold rotational symmetry. For example, the conductive alignment layer 104 should have a hexagonal-most dense structure, a face-centered cubic structure, or a structure equivalent thereto. Here, the hexagonal-most-dense structure or a structure equivalent to the face-centered cubic structure includes a crystal structure in which the c-axis is not 90 degrees to the a-axis and b-axis. The conductive alignment layer 104 using a conductive material having a hexagonal-most-dense structure or a structure equivalent thereto is preferably oriented in the (0001) direction, that is, in the c-axis direction with respect to the amorphous substrate 102 (hereinafter referred to as (0001) alignment of the hexagonal-most-dense structure). The conductive alignment layer 104 with a face-centered cubic structure or equivalent structure should be oriented in the (111) direction with respect to the amorphous substrate 102 (hereinafter referred to as (111) alignment of the face-centered cubic structure).

The conductive alignment layer 104 is arranged between the amorphous substrate 102 and the gallium nitride-based semiconductor layer 106. The gallium nitride-based semiconductor layer 106 is preferably crystalline, and the conductive alignment layer 104 functions as a buffer layer. The conductive alignment layer 104 has crystallinity as described above, which allows crystallization of the gallium nitride-based semiconductor layer 106 to be grown on it and also promotes crystallization. That is, the conductive alignment layer 104 has a crystalline surface having 6-fold rotational symmetry, such as a hexagonal close-packed structure or a face-centered cubic structure, so that the c-axis of the gallium nitride-based semiconductor layer 106 can be controlled to grow in the direction of the film thickness.

Furthermore, the crystallinity of the gallium nitride-based semiconductor layer 106 is affected by the surface condition of the conductive alignment layer 104. Therefore, the conductive alignment layer 104 should have a flat surface. For example, the conductive alignment layer 104 should have a surface arithmetic mean roughness (Ra) of less than 2.3 nm. The conductive alignment layer 104 having a flat surface can enhance the crystallinity of the gallium nitride-based semiconductor layer 106.

The conductive alignment layer 104 should be thin in order to obtain a flat surface. For example, the conductive alignment film 104 should have a thickness of 100 nm or less, preferably 50 nm or less. A flat surface can be formed while still having crystallinity, by making the thickness of the conductive alignment film 104 50 nm or less.

The conductive alignment layer 104 should be conductive in order to function as an electrode for the gallium nitride-based semiconductor device. To achieve the function as an electrode, the conductive alignment layer 104 should be formed of a metallic material. For example, the conductive alignment layer 104 is preferably formed of titanium (Ti), aluminum (AI), and other metals such as silver (Ag), nickel (Ni), copper (Cu), strontium (Sr), rhodium (Rh), palladium (Pd), iridium (Ir), platinum (Pt), gold (Au (Au), and the like can be used. Conductive metal oxides such as zinc oxide (ZnO) and titanium dioxide (TiO2) can also be used for the conductive alignment layer 104.

The conductive alignment layer 104 is prepared by the sputtering method, using a sputtering target formed of the metal material to be deposited. The conductive alignment layer 104 may also be prepared by vacuum evaporation or electron beam evaporation.

The gallium nitride-based semiconductor layer 106 includes at least one gallium nitride (GaN) layer. The gallium nitride is a compound of gallium (Ga) and nitrogen (N) and is a semiconductor. The gallium nitride layer should have a stoichiometric composition, although it may deviate from the stoichiometric composition. The gallium nitride layer used as the gallium nitride-based semiconductor layer 106 preferably has crystallinity. The crystallinity of the gallium nitride layer is preferably single crystal, but may be polycrystalline, microcrystalline, or nanocrystalline. The crystalline structure of the gallium nitride layer should preferably have a wurtzite structure. The gallium nitride layer used as the gallium nitride-based semiconductor layer 106 preferably has a c-axis alignment or (111) alignment.

The conductive type of the gallium nitride layer used as the gallium nitride-based semiconductor layer 106 may be substantially intrinsic, or it may have n-type or p-type conductivity. The gallium nitride layer with n-type conductivity may be doped with one element selected from silicon (Si) or germanium (Ge) as an n-type dopant, even though it does not contain dopants to control valence electrons. The gallium nitride layer with p-type conductivity may be doped with one element selected from magnesium (Mg), zinc (Zn), cadmium (Cd), and beryllium (Be) as a p-type dopant. The n-type gallium nitride layer should have a carrier concentration of 1×10¹⁸/cm³ or higher when doped with dopants. The p-type gallium nitride layer, when doped with dopants, should have a carrier concentration of 5×10¹⁶/cm³ or higher. The substantially intrinsic (otherwise known as high resistivity) gallium nitride layer may contain zinc (Zn) as a dopant.

The gallium nitride layer used as the gallium nitride-based semiconductor layer 106 may contain one or more elements selected from indium (In), aluminum (Al), and arsenic (As). These elements can adjust the band gap of the gallium nitride layer.

The gallium nitride layer used as the gallium nitride-based semiconductor layer 106 is arranged on top of the conductive alignment layer 104. As mentioned above, the surface of the conductive alignment layer 104 (the surface in contact with the gallium nitride layer) contains crystal planes with rotational symmetry or c-axis alignment, resulting in a gallium nitride layer with c-axis orientation or (111) alignment. The gallium nitride layer may contain an amorphous structure near the interface where it contacts the conductive alignment layer 104, but it should be crystalline in bulk. The crystalline nature of the gallium nitride-based semiconductor layer 106 can enhance the performance of the gallium nitride-based semiconductor device 100. For example, when the gallium nitride-based semiconductor device 100 is a light-emitting device, it is possible to increase the luminescence intensity, and when it is an active device such as a transistor, it is possible to increase the carrier mobility.

The gallium nitride-based semiconductor layer 106 is deposited at a temperature below the strain point of the amorphous substrate 102. Generally, the gallium nitride layer is deposited by the MOCVD method (metal organic chemical vapor deposition), but this deposition method is not necessarily suitable for the heat resistance of the amorphous substrate 102 because of the high process temperature. The gallium nitride-based semiconductor layer 106 is prepared by sputtering, which makes it possible to deposit the film at a temperature below the strain point of the amorphous substrate 102, in this embodiment.

For example, the gallium nitride layer used as the gallium nitride-based semiconductor layer 106 is prepared by a sputtering method while the amorphous substrate 102 is heated to 100 to 600° C. Since the conductive alignment layer 104 is formed on the deposited surface of the amorphous substrate 102, a crystalline (preferably c-axis aligned) gallium nitride layer can be grown by the sputtering method even at a substrate temperature below 600° C.

The gallium nitride layer used as the gallium nitride-based semiconductor layer 106 is deposited by sputtering a sintered gallium nitride target and using argon (Ar) or a mixture of argon (Ar) and nitrogen (N₂) as the sputter gas. Various types of sputtering may be applied. For example, the following sputtering methods can be applied: two-pole sputtering, magnetron sputtering, dual magnetron sputtering, opposed target sputtering, ion beam sputtering, and inductively coupled plasma (ICP) sputtering.

A thickness of the gallium nitride-based semiconductor layer 106 is not limited and is set appropriately according to the structure of the device. The gallium nitride-based semiconductor layer 106 may be a single layer, or a plurality of layers with different conductive layers and/or compositions may be stacked.

The upper electrode layer 108 is arranged above the gallium nitride-based semiconductor layer 106. The upper electrode layer 108 functions as an electrode of the gallium nitride-based semiconductor device 100. The upper electrode layer 108 is arranged to form an ohmic contact with the gallium nitride-based semiconductor layer 106. Depending on the structure of the device, the upper electrode layer 108 may be omitted. The upper electrode layer 108 is formed of a metallic material such as aluminum (AI), titanium (Ti), platinum (Pt), nickel (Ni), or tantalum (Ta). The upper electrode layer 108 may be formed of a metal oxide that is conductive and used as a transparent electrode, such as indium tin oxide (ITO), zinc oxide (ZnO), and indium zinc oxide (IZO).

The auxiliary electrode layer 110 is arranged so that it is in contact with the conductive alignment layer 104. FIG. 1A shows a structure in which the auxiliary electrode layer 110 is arranged so that it is in contact with the top surface (the side surface of the gallium nitride-based semiconductor layer 106) and the side surface of the conductive alignment layer 104. FIG. 1B shows a structure in which the auxiliary electrode layer 110 is arranged in contact with the bottom surface (the side surface of the amorphous substrate 102) of the conductive alignment layer 104. As shown in FIG. 1A and FIG. 1B, an outer periphery of the conductive alignment layer 104 is arranged so that it protrudes from the gallium nitride-based semiconductor layer 106, and the auxiliary electrode layer 110 makes contact at the protruding portion, thereby increasing the contact area. It is possible to prevent the gallium nitride-based semiconductor layer 106 from overlapping the step formed by the auxiliary electrode layer 110 by bringing the auxiliary electrode layer 110 into contact with the conductive alignment layer 104 at the protruding portion, so that the crystallinity is not affected.

While the conductive alignment layer 104 is formed with a thickness of 50 nm or less, the auxiliary electrode layer 110 is formed with a thickness of 50 nm or more, preferably 100 nm to 1000 nm, to reduce electrical resistance. Therefore, as shown in FIG. 1B, when the auxiliary electrode layer 110 is in contact with the lower side of the conductive alignment layer 104, the edge should have a tapered shape. A tapered edge of the auxiliary electrode layer 110 in a cross-sectional view can prevent step disconnections of the conductive alignment layer 104.

Although FIG. 1A and FIG. 1B only show the cross-sectional structure, the auxiliary electrode layer 110 is preferably arranged so as to surround the periphery of the conductive alignment layer 104. When the auxiliary electrode layer 110 is arranged so that it is in contact with the conductive alignment layer 104, an electrically connected state (conductive state) is formed.

The conductive alignment layer 104 is used as the electrode of the gallium nitride-based semiconductor device 100. When the conductive alignment layer 104 has a thickness of 50 nm or less, as described above, the electrode becomes highly resistive. For example, the resistivity of titanium (Ti) used as the conductive alignment layer 104 is 100 nom, which is one order of magnitude higher than that of aluminum (Al). Therefore, when titanium (Ti) is used as the conductive alignment layer 104, there is concern regarding the adverse effect on device characteristics due to the resistance loss of the electrode. For example, if the gallium nitride-based semiconductor device 100 is a light-emitting device, the problem of non-uniformity of luminescence intensity within the plane can occur. In other words, if the conductive alignment layer 104 is aligned with the power supply line, the luminescence intensity may decrease as the conductive alignment layer 104 moves away from the connection.

In order to address such a problem, the gallium nitride-based semiconductor device 100 shown in FIG. 1A and FIG. 1B is arranged with an auxiliary electrode layer 110, thereby eliminating the problem of resistance loss of the conductive alignment layer 104. In other words, the problem of resistance loss can be eliminated by providing the auxiliary electrode layer 110 so that it is electrically connected to the conductive alignment layer 104 and reduces the resistivity of the surface resistance of the conductive alignment layer 104. It is possible to use the conductive alignment layer 104 as it is as an electrode even when the area of the gallium nitride-based semiconductor device 100 is increased by providing the auxiliary electrode layer 110, thereby suppressing the effect of high resistance of the electrode.

The conductive materials used to form the auxiliary electrode layer 110 are metallic materials such as aluminum (Al), titanium (Ti), silver (Ag), molybdenum (Mo), and tantalum (Ta). The auxiliary electrode layer 110 is preferably thicker than the conductive alignment film 104 for lower resistance. The auxiliary electrode layer 110 may have a structure (for example, Ti/Al/Ti) in which an aluminum (Al) film is sandwiched by a high melting point metal film such as titanium (Ti) to increase heat resistance.

The auxiliary electrode layer 110 in the gallium nitride-based semiconductor device 100 is not limited to the structures shown in FIG. 1A and FIG. 1B, but can be arranged in a variety of structures. Some embodiments of the auxiliary electrode layer 110 are described below as examples.

### Second Embodiment

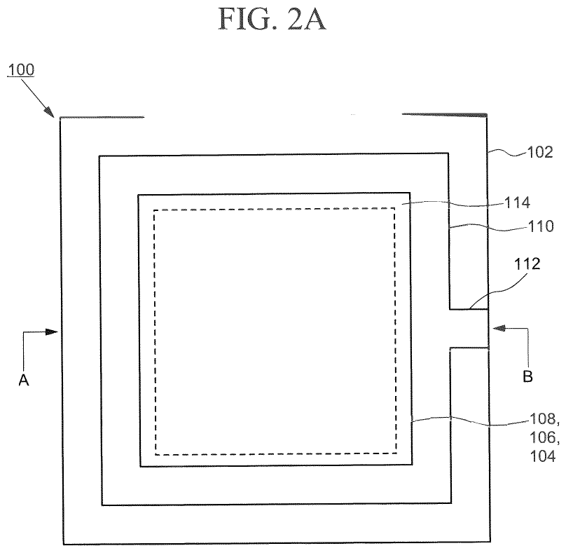

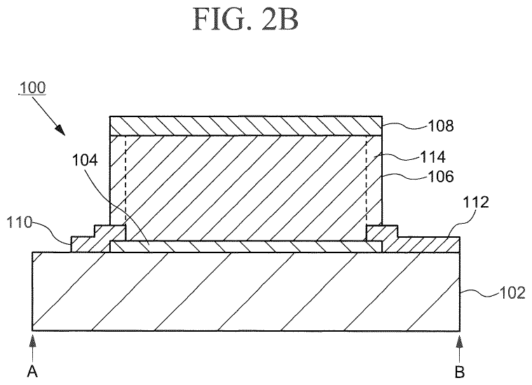

FIG. 2A and FIG. 2B show a structure of a gallium nitride-based semiconductor device 100 according to the second embodiment. FIG. 2A shows a plan view of the gallium nitride-based semiconductor device 100 of the present embodiment, and FIG. 2B shows a cross-sectional view corresponding to the region between A and B shown in FIG. 2A.

The gallium nitride-based semiconductor device 100 shown in FIG. 2A and FIG. 2B has a structure in which an auxiliary electrode layer 110 contacts a conductive alignment layer 104 from a side and top surface and overlaps a gallium nitride-based semiconductor layer 106 on the conductive alignment layer 104. The auxiliary electrode layer 110 is arranged to surround a periphery portion of the conductive alignment layer 104. The auxiliary electrode layer 110 may be connected to a wiring 112. In other words, the auxiliary electrode layer 110 may be formed of the same conductive layer as the conductive layer forming the wiring 112. It is possible to simplify the structure by forming the auxiliary electrode layer 110 and the wiring 112 with the same conductive layer, thereby eliminating the need for connecting parts such as contact holes.

According to the structure of the auxiliary electrode layer 110 shown in FIG. 2A and FIG. 2B, the auxiliary electrode layer 110 can prevent the characteristic degradation of the gallium nitride-based semiconductor device 100 due to the high resistance of the conductive alignment layer 104. For example, when the gallium nitride-based semiconductor device 100 is a light-emitting device, uneven brightness in the light-emitting region can be eliminated, and in the case of an active device such as a transistor, increased power consumption can be suppressed. Since there is no need to provide a protrusion in the conductive alignment layer 104, the size of the gallium nitride-based semiconductor device 100 can be reduced. As a result, it is possible to increase the integration when attempting to integrate devices.

The crystallinity of the gallium nitride-based semiconductor layer 106 is affected by the conductive alignment layer 104. Since the auxiliary electrode layer 110 is a thick film and its crystallinity is different from that of the conductive alignment layer 104, there is concern regarding the effect on the gallium nitride-based semiconductor layer 106. Specifically, the periphery portion 114 of the gallium nitride-based semiconductor layer 106 shown in FIG. 2A and FIG. 2B may be different from the crystallinity of the region inner portion of the gallium nitride-based semiconductor layer 106 than the periphery portion 114 of the gallium nitride-based semiconductor layer 106. For example, the periphery portion 114 of the gallium nitride-based semiconductor layer 106 may have poorer crystallinity than the inner portion and be in an amorphous state due to the influence of the auxiliary electrode layer 110. In this case, if the resistance of the outer periphery 114 is higher, the leakage current flowing through the end face of the gallium nitride-based semiconductor layer 106 between the upper electrode layer 108 and the auxiliary electrode layer 110 is reduced.

A width of the auxiliary electrode layer 110 overlapping the gallium nitride-based semiconductor layer 106 is a small fraction of the total width of the gallium nitride-based semiconductor layer 106. Therefore, even if a region with different crystallinity is formed in the peripheral portion 114 as described above, the effect on the gallium nitride-based semiconductor device 100 is negligible. Rather, the benefit of the auxiliary electrode layer 110 on the gallium nitride-based semiconductor device 100 is that the effect of the high resistance of the conductive alignment layer 104 is eliminated. The gallium nitride-based semiconductor device 100 according to the present embodiment is similar to that shown in the first embodiment except that the auxiliary electrode layer 110 has a region overlapping the gallium nitride-based semiconductor layer 106, and the same effects are obtained.

### Third Embodiment

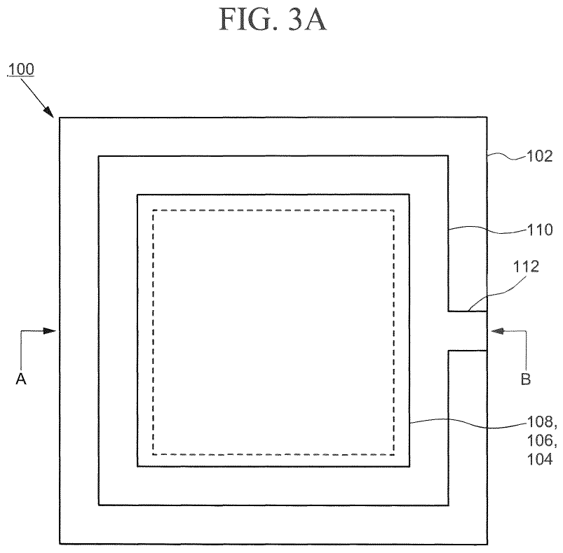

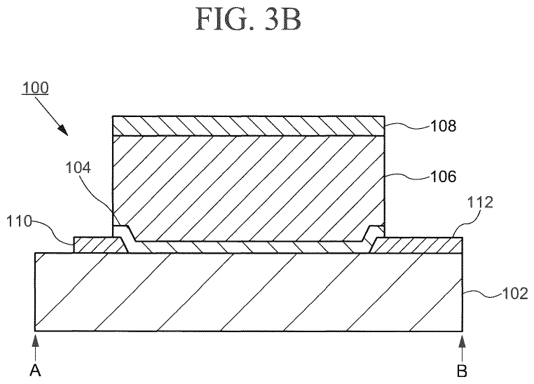

FIG. 3A and FIG. 3B show a structure of a gallium nitride-based semiconductor device 100 according to the third embodiment. FIG. 3A shows a plan view of the gallium nitride-based semiconductor device 100 according to the present embodiment, and FIG. 3B shows a cross-sectional view corresponding to the region between A and B shown in FIG. 3A.

The gallium nitride-based semiconductor device 100 shown in FIG. 3A and FIG. 3B includes a structure in which an auxiliary electrode layer 110 is in contact with a bottom surface of a conductive alignment layer 104. The auxiliary electrode layer 110 is arranged to surround the periphery portion of the conductive alignment layer 104. The auxiliary electrode layer 110 may be connected to a wiring 112, and the auxiliary electrode layer 110 may be formed of the same conductive layer as the conductive layer forming the wiring 112.

As shown in FIG. 3B, due to the structure where the auxiliary electrode layer 110 contacts the bottom surface of the conductive alignment layer 104, the gallium nitride-based semiconductor layer 106 has a structure where the entire bottom surface contacts the conductive alignment layer 104. Therefore, the crystallinity of the gallium nitride-based semiconductor layer 106 is uniform over the entire surface. The gallium nitride-based semiconductor layer 106 includes a portion overlapping a step formed by the conductive alignment layer 104 overlapping the auxiliary electrode layer 110. However, similar to the second embodiment, an area of the step portion accounts for only a small percentage of the total area, and its effect on the gallium nitride-based semiconductor device 100 is minor. When the edge of the auxiliary electrode layer 110 is tapered, the stepped portion is also tapered, and thus has almost no effect on the crystallinity of the gallium nitride-based semiconductor layer 106. Thus, the structures shown in FIG. 3A and FIG. 3B are less affected by the formation of the auxiliary electrode layer in the gallium nitride-based semiconductor layer 106 than the structure shown in the first embodiment.

The gallium nitride-based semiconductor device 100 according to the present embodiment is similar to the second embodiment, except that the auxiliary electrode layer 110 contacts the bottom surface of the conductive alignment layer 104, and the same effect is obtained.

### Fourth Embodiment

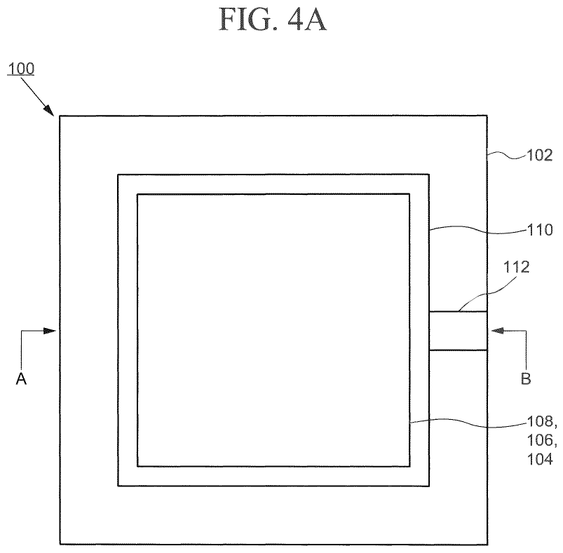

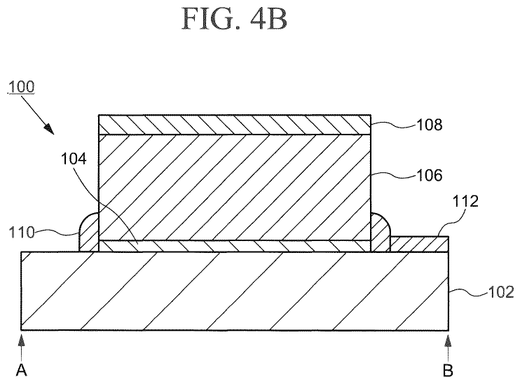

FIG. 4A and FIG. 4B show a structure of a gallium nitride-based semiconductor device 100 according to the fourth embodiment. FIG. 4A shows a plan view of the gallium nitride-based semiconductor device 100 according to the present embodiment, and FIG. 4B shows a cross-sectional view corresponding to the region between A and B shown in FIG. 4A.

The gallium nitride-based semiconductor device 100 shown in FIG. 4A and FIG. 4B includes an auxiliary electrode layer 110 in contact with a side surface of a conductive alignment layer 104. The auxiliary electrode layer 110 may be in contact not only with the conductive alignment layer 104, but also with a side surface of the gallium nitride-based semiconductor layer 106. The auxiliary electrode layer 110 is preferably arranged to contact the conductive alignment layer 104 and the outer side of the gallium nitride-based semiconductor layer 106 over the entire circumference, in this embodiment.

Although FIG. 4B does not show the details, the gallium nitride-based semiconductor layer 106 may have a multilayer structure. For example, when the gallium nitride-based semiconductor device 100 is a light emitting device, the gallium nitride-based semiconductor layer 106 has a structure in which, from the bottom layer side, an n-type gallium nitride semiconductor layer, an active layer (light emitting layer), and a p-type gallium nitride semiconductor layer are stacked. In such a case, the auxiliary electrode layer 110 is preferably arranged in contact with a side surface of the n-type gallium nitride semiconductor layer, which is the lowest layer.

The auxiliary electrode layer 110 shown in FIG. 4A and FIG. 4B is formed after the gallium nitride-based semiconductor layer 106 and the upper electrode layer 108 are formed on the conductive alignment layer 104. Specifically, as shown in FIG. 4B, after the conductive alignment layer 104, the gallium nitride-based semiconductor layer 106, and the upper electrode layer 108 are formed on the amorphous substrate 102, a conductive film is formed on the amorphous substrate 102 to cover a top surface and sides of this stacked body. The auxiliary electrode layer 110 is formed by etching back the conductive film by anisotropic etching to leave a conductive layer on the side of the stacked layers. The conductive layer for forming the auxiliary electrode layer 110 is formed of a metallic material such as titanium (Ti), aluminum (AI), silver (Ag), molybdenum (Mo), or tantalum (Ta). The auxiliary electrode layer 110 may be connected to a wiring 112 to connect to an adjacent element or power supply.

Thus, it is possible to prevent the auxiliary electrode layer 110 from affecting the deposition of the gallium nitride-based semiconductor layer 106 by providing the auxiliary electrode layer 110 in contact with the side surface of the conductive alignment layer 104. In other words, it is possible to prevent the crystallinity of the gallium nitride-based semiconductor layer 106 from being affected by forming the auxiliary electrode layer 110 after depositing the gallium nitride-based semiconductor layer 106 on the conductive alignment layer 104 and further forming the upper electrode layer 108. As a result, it is possible to obtain satisfactory device characteristics.

The gallium nitride-based semiconductor device 100 according to the present embodiment is similar to that shown in the first embodiment, except that the auxiliary electrode layer 110 has a structure in contact with the side surface of the conductive alignment layer 104, and the same advantageous effects are obtained.

### Fifth Embodiment

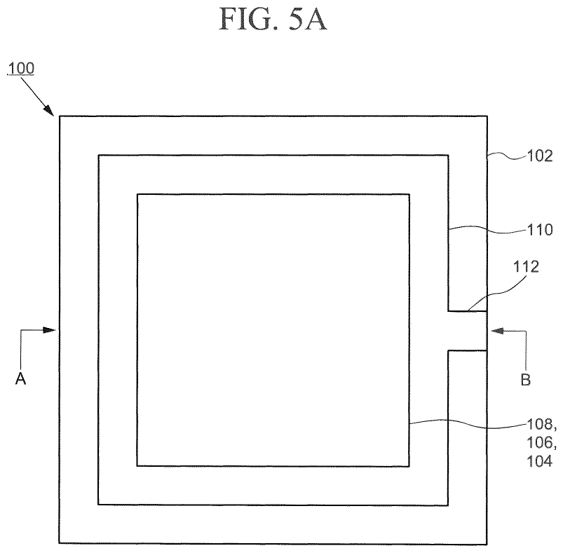

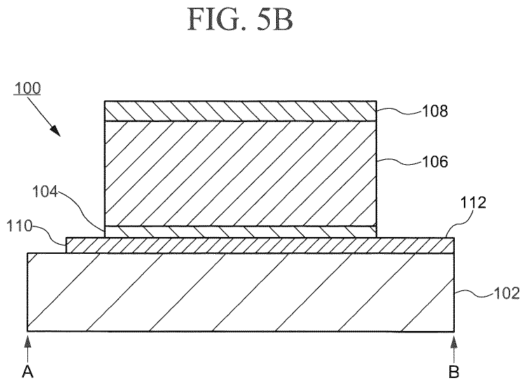

FIG. 5A and FIG. 5B show the structure of a gallium nitride-based semiconductor device 100 according to the fifth embodiment. FIG. 5A shows a plan view of the gallium nitride-based semiconductor device 100 according to the present embodiment, and FIG. 5B shows a cross-sectional view corresponding to the region between A and B shown in FIG. 5A.

The gallium nitride-based semiconductor device 100 shown in FIG. 5A and FIG. 5B includes a structure in which an auxiliary electrode layer 110 contacts an entire surface of a lower surface of a conductive alignment layer 104. The auxiliary electrode layer 110 may have a structure continuous from a wiring 112, and the auxiliary electrode layer 110 may be formed of the same conductive layer as the conductive layer forming the wiring 112. As shown in FIG. 5A and FIG. 5B, the auxiliary electrode layer 110 may have an area larger than that of the conductive alignment layer 104, and its ends may be disposed on the outside. Although not shown, the auxiliary electrode layer 110 may be the same size as the conductive alignment layer 104 or have a smaller area than the conductive alignment layer 104, and the ends may be disposed inside.

As shown in FIG. 5A and FIG. 5B, when the auxiliary electrode layer 110 contacts the entire surface of the lower surface of the conductive alignment layer 104, the contact region is increased, and it is possible to reduce the resistance more effectively. That is, it is possible to substantially reduce the sheet resistance (surface resistance) of the conductive alignment layer 104.

The structure shown in FIG. 5A and FIG. 5B includes a structure in which the gallium nitride-based semiconductor layer 106 contacts the entire surface of the conductive alignment layer 104. Therefore, it is possible to make the crystallinity of the gallium nitride-based semiconductor layer 106 uniform. With a larger area of the auxiliary electrode layer 110, it is possible to eliminate the effect of the stepped portion as well, since no steps are formed in the conductive alignment layer 104. Thus, the structure shown in FIG. 5A and FIG. 5B has a structure in which the gallium nitride-based semiconductor layer 106 is less affected by the formation of the auxiliary electrode layer than the structure shown in the second and third embodiments.

The gallium nitride-based semiconductor device 100 according to the present embodiment is similar to that shown in the first embodiment except that the auxiliary electrode layer 110 contacts the lower surface of the conductive alignment layer 104, and the same advantageous effect is obtained.

### Sixth Embodiment

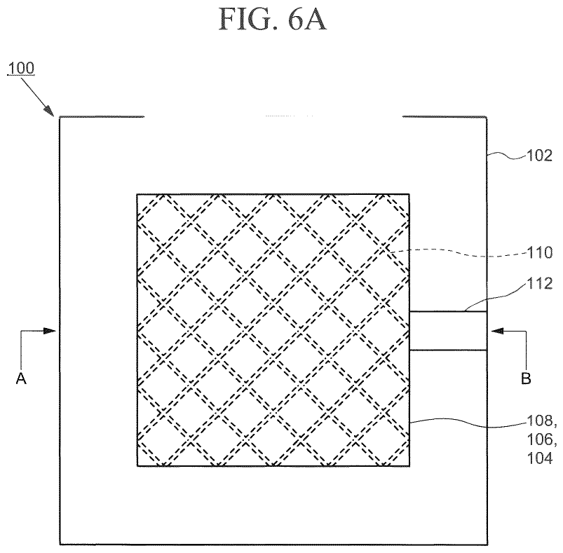

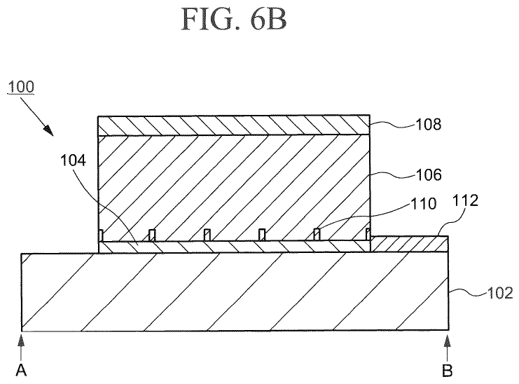

FIG. 6A and FIG. 6B show a structure of a gallium nitride-based semiconductor device 100 according to the sixth embodiment. FIG. 6A shows a plan view of the gallium nitride-based semiconductor device 100 according to the present embodiment, and FIG. 6B shows a cross-sectional view corresponding to the region between A and B shown in FIG. 6A.

The gallium nitride-based semiconductor device 100 shown in FIG. 6A and FIG. 6B includes an auxiliary electrode layer 110 having a lattice-like pattern and is arranged on an upper surface of a conductive alignment layer 104. The lattice pattern of the auxiliary electrode layer 110 is arranged to spread over the entire surface of the conductive alignment layer 104. The auxiliary electrode layer 110 having a lattice pattern may be connected to a wiring 112 at the edge. The auxiliary electrode layer 110 is formed of a metallic material such as aluminum (Al) or silver (Ag), which has lower resistance than the metal that forms the conductive alignment layer 104. In order to minimize the influence on the crystallinity of the gallium nitride-based semiconductor layer 106, a line width of the lattice pattern is narrowed.

It is possible to substantially reduce the sheet resistance (surface resistance) of the conductive alignment layer 104 by the structure of the auxiliary electrode layer 110 shown in FIG. 6A and FIG. 6B. Since the lattice-like pattern of the auxiliary electrode layer 110 extends over the entire surface of the conductive alignment layer 104, it is advantageous to increase the area. For example, when the gallium nitride-based semiconductor device 100 is a light-emitting device, it is possible to suppress uneven luminance (luminance gradient) even when the light-emitting region has a large area.

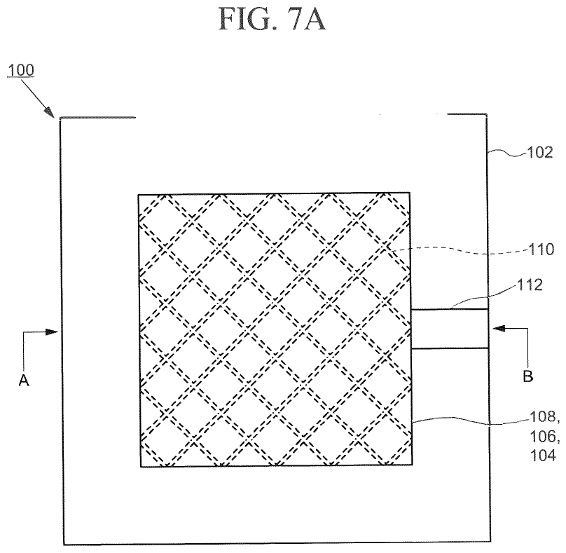

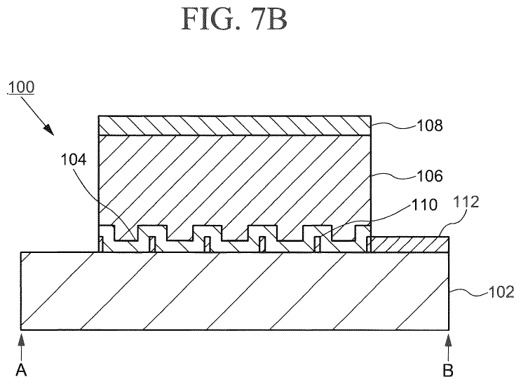

The gallium nitride-based semiconductor device 100 shown in FIG. 7A and FIG. 7B shows a structure in which the auxiliary electrode layer 110 having a lattice pattern is arranged in contact with the bottom surface of the conductive alignment layer 104. FIG. 7A shows a plan view of the gallium nitride-based semiconductor device 100 according to the present embodiment, and FIG. 7B shows a cross-sectional view corresponding to the region between A and B shown in FIG. 7A. It is possible to lower the resistance and eliminate the effect on the crystallinity of the gallium nitride-based semiconductor layer 106 by making the auxiliary electrode layer 110 having a lattice pattern contact the conductive alignment layer 104 from the bottom surface of the conductive layer 104. In other words, the auxiliary electrode layer 110 with a lattice pattern is arranged between the amorphous substrate 102 and the conductive alignment layer 104, so that the entire surface of the gallium nitride-based semiconductor layer 106 can be in contact with the conductive alignment layer 104 to obtain excellent crystallinity.

Although not shown, the lattice pattern of the auxiliary electrode layer 110 may be replaced by a stripe pattern or a mesh pattern. It is possible to combine the configuration of the auxiliary electrode layer 110 shown in this embodiment with the auxiliary electrode layers shown in the first and fourth embodiments as appropriate. For example, the auxiliary electrode layer 110 may be arranged on the outer periphery and in the plane of the conductive alignment layer 104 so that the lattice pattern shown in this embodiment is connected to the auxiliary electrode layer 110 arranged on the outer periphery of the conductive alignment layer 104 shown in the first embodiment.

The gallium nitride-based semiconductor device 100 according to the present embodiment is similar to that shown in the first embodiment except that the auxiliary electrode layer 110 contacts the bottom surface of the conductive alignment layer 104, and the same advantageous effect is obtained.

### Seventh Embodiment

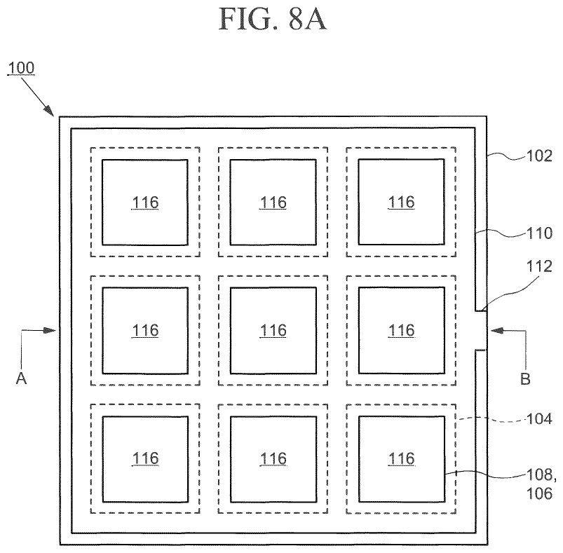

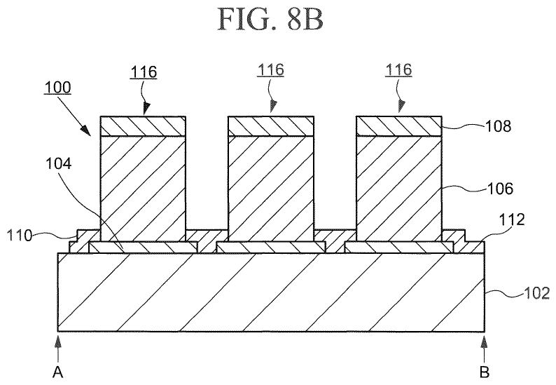

FIG. 8A and FIG. 8B show the structure of a gallium nitride-based semiconductor device 100 according to the seventh embodiment. FIG. 8A shows a plan view of the gallium nitride-based semiconductor device 100 according to the present embodiment, and FIG. 8B shows a cross-sectional view corresponding to the region between A and B shown in FIG. 8A.

FIG. 8A and FIG. 8B show a gallium nitride-based semiconductor device 100 having a plurality of stacked layers 116 where a conductive alignment layer 104, a gallium nitride-based semiconductor layer 106, and an upper electrode layer 108 are arranged on an amorphous substrate 102. Each individual stacked layer 116 has the structure shown in the second embodiment. The plurality of stacked layers 116 are arranged spaced apart on the amorphous substrate 102, and an auxiliary electrode layer 110 is arranged in the region where the plurality of stacked layers 116 are spaced apart. The auxiliary electrode layer 110 is arranged to connect adjacent stacked layers 116. The auxiliary electrode layer 110 is arranged to spread over the entire region where the plurality of stacked layers 116 are arranged. This arrangement not only electrically connects the plurality of stacked layers 116, but also lowers the resistance of the stacked layers 116.

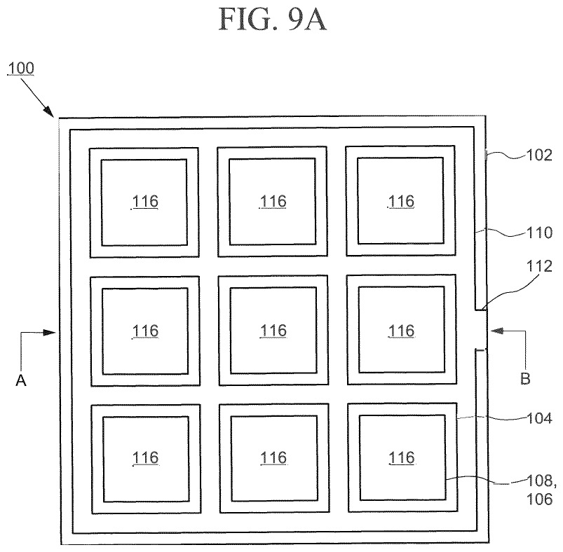

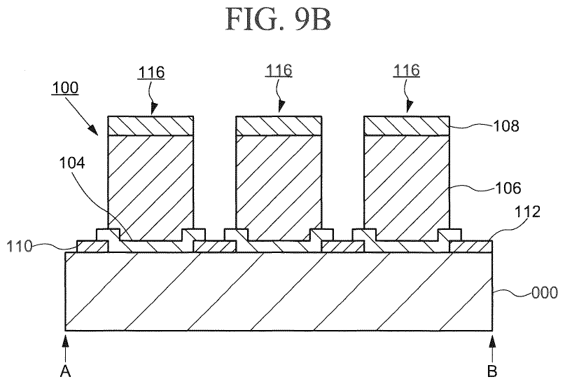

FIG. 9A and FIG. 9B show the case where each of the plurality of stacked layers 116 has the same structure as that shown in the third embodiment. FIG. 9A shows a plan view of the gallium nitride-based semiconductor device 100, and FIG. 9B shows a cross-sectional view corresponding to between A and B shown in FIG. 9A. As shown in FIG. 9A and FIG. 9B, adjacent stacked layers 116 may also be connected to each other by a configuration in which the auxiliary electrode layer 110 is aligned on the lower side of the conductive alignment layer 104.

FIG. 8A and FIG. 8B and FIG. 9A and FIG. 9B show an example in which all of the conductive alignment layers 104 of the plurality of stacked layers 116 are connected to be at the same potential, but the configuration of the auxiliary electrode layer 110 is not limited to the examples shown in the figures. For example, the auxiliary electrode layer 110 may be arranged so that the plurality of stacked layers 116 arranged in a matrix are connected in the line or column direction, forming a structure in which the plurality of stacked layers 116 are connected in series and parallel on the amorphous substrate 102.

The gallium nitride-based semiconductor device 100 shown in this embodiment is advantageous, for example, in realizing a light-emitting device with a relatively large area. The plurality of stacked layers 116 does not require a large individual area, can prevent uneven luminance due to the resistance of the conductive alignment layer 104, and can achieve low resistance with the auxiliary electrode layer 110. Thereby, a light emitting device with uniform luminance distribution during emission is obtained.

### Eighth Embodiment

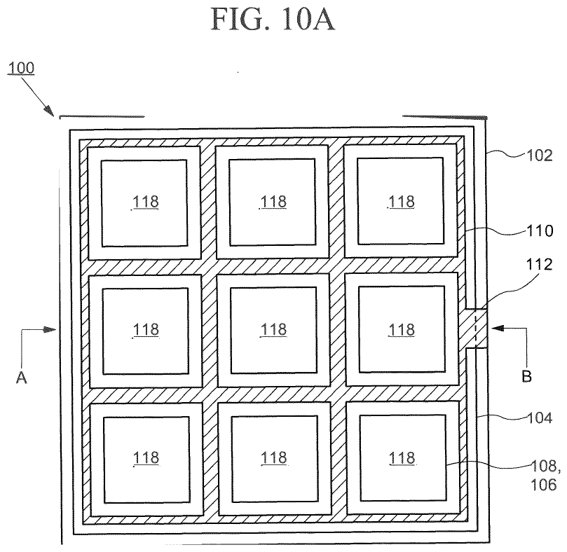

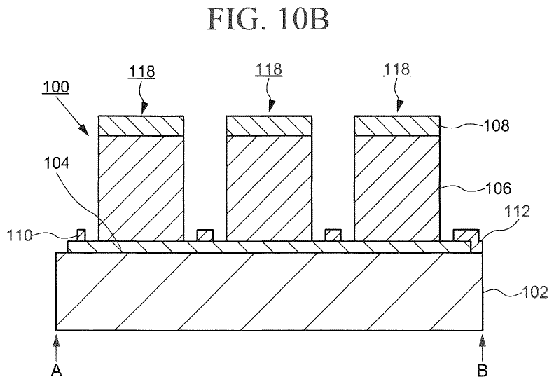

FIG. 10A and FIG. 10B show a structure of gallium nitride-based semiconductor device 100 according to the eighth embodiment. FIG. 10A shows a plan view of the gallium nitride-based semiconductor device 100 according to the present embodiment, and FIG. 10B shows a cross-sectional view corresponding to the region between A and B shown in FIG. 10A.

The gallium nitride-based semiconductor device 100 shown in FIG. 10A and FIG. 10B has the same configuration of a plurality of stacked layers 118 as in the seventh embodiment, but the structure of the conductive alignment layer 104 is different. The configuration of the conductive alignment layer 104 is continuous and common across the plurality of stacked layers 118 in this embodiment. In other words, the gallium nitride-based semiconductor device 100 according to the present embodiment has a structure in which the conductive alignment layer 104 is aligned on the amorphous substrate 102, on which a plurality of divided gallium nitride-based semiconductor layers and an upper electrode are arranged.

An auxiliary electrode layer 110 is arranged in contact with the top surface of the conductive alignment layer 104 in the region where the gallium nitride-based semiconductor layer 106, which is divided into a plurality of layers, is separated from the top surface of the conductive alignment layer 104. In other words, as shown in FIG. 10A, the auxiliary electrode layer 110 is arranged in a lattice pattern on the conductive alignment layer 104, and the patterns of the gallium nitride-based semiconductor layer 106 and the upper electrode layer 108 are arranged in the openings of the lattice. According to this configuration, the auxiliary electrode layer 110 does not affect the crystallinity of the gallium nitride-based semiconductor layer 106. It is possible to make the auxiliary electrode layer 110 thicker and to achieve lower resistance as an auxiliary electrode for the conductive alignment layer 104.

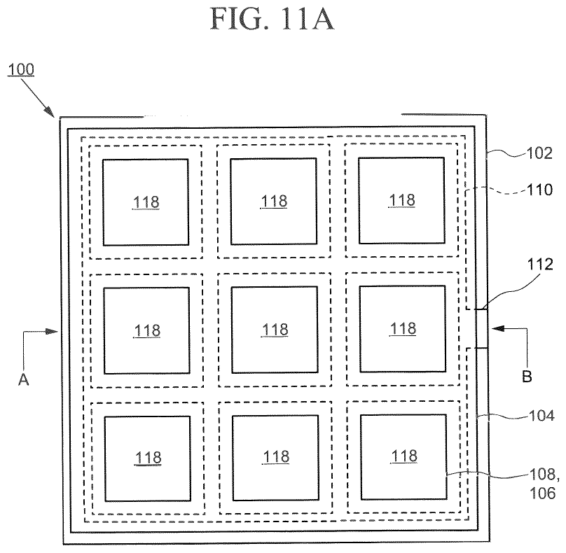

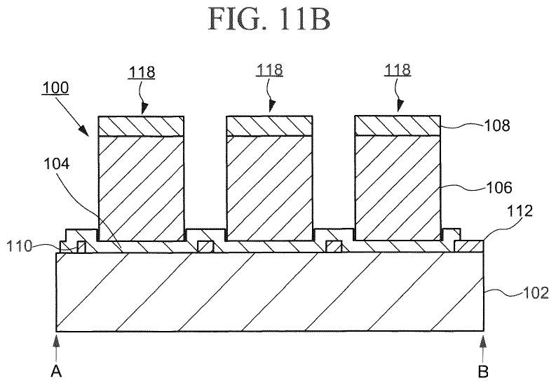

FIG. 11A and FIG. 11B show a structure in which the auxiliary electrode layer 110 is arranged on the lower side of the conductive alignment layer 104. FIG. 11A shows a plan view of the gallium nitride-based semiconductor device 100, and FIG. 11B shows a cross-sectional view corresponding to between A and B shown in FIG. 11A. As shown in FIG. 11A and FIG. 11B, it is possible to achieve lower resistance by the configuration in which the auxiliary electrode layer 110 is aligned on the lower side of the conductive alignment layer 104.

The gallium nitride-based semiconductor device 100 shown in this embodiment, as in the seventh embodiment, is advantageous in realizing a relatively large-area light-emitting device. The individual light-emitting regions do not need to have a large area, and the auxiliary electrode layer 110 prevents uneven luminance due to the resistance of the conductive alignment layer 104. This enables a light emitting device with uniform luminance distribution when emitting light.

### Ninth Embodiment

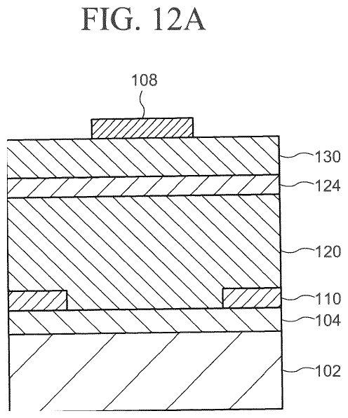

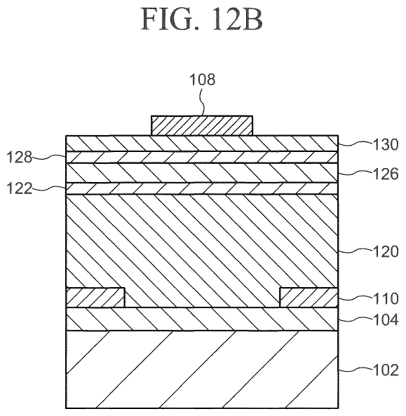

This embodiment shows a detailed example of a gallium nitride-based semiconductor layer 106. The gallium nitride-based semiconductor layer 106 may include a plurality of gallium nitride layers of different conductive types. FIG. 12A shows the configuration of the gallium nitride-based semiconductor layer 106 when the gallium nitride-based semiconductor device 100 is a light emitting device. The gallium nitride-based semiconductor layer 106 has a structure in which an n-type gallium nitride layer 120, an emissive layer 124, and a p-type gallium nitride layer 130 are stacked on top of the conductive layer 104. The top electrode layer 108 is arranged above the p-type gallium nitride layer 130. The top electrode layer 108 is formed of metallic materials such as gold (Au), titanium (Ti)-gold (Au) alloy, or transparent conductive layers such as indium tin oxide (ITO). The structure of the light-emitting layer 124 varies and may be formed by a quantum well layer with alternating layers of gallium nitride (GaN) and indium gallium nitride (InGaN) layers.

FIG. 12B shows another configuration of gallium nitride semiconductor layers 106 applied to light emitting devices. FIG. 12B has a stacked structure of the n-type gallium nitride layer 120, the n-type aluminum gallium nitride layer 122, the indium gallium nitride layer 126, the p-type aluminum gallium nitride layer 128, and the p-type gallium nitride layer 130. Each of these layers is prepared by the sputtering method. Since each of these layers has a different composition, each layer is deposited using sputtering targets that contain dopants corresponding to the respective conductivity types. One element selected from silicon (Si) and germanium (Ge) is used as the n-type dopant, and one element selected from magnesium (Mg), zinc (Zn), cadmium (Cd), and beryllium (Be) is used as the p-type dopant. Since each of these layers is preferably deposited continuously in a vacuum, a multi-chamber sputtering system is used.

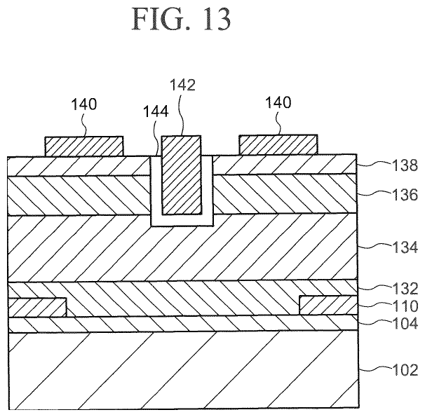

FIG. 13 shows the configuration of the gallium nitride-based semiconductor layer 106 when the gallium nitride-based semiconductor device 100 is a transistor. The gallium nitride-based semiconductor layer 106 has a structure in which an n+ type gallium nitride layer 132, an n-type gallium nitride layer 134, a p-type gallium nitride layer 136, and an n-type gallium nitride layer 138 are stacked on top of the conductive layer 104. A source electrode 140 is arranged above the n-type gallium nitride layer 138, and the conductive alignment layer 104 is used as the drain electrode. A gate electrode 142 has a trench gate structure and is arranged to be embedded in the p-type gallium nitride layer 130 through a gate insulating layer 144. Each layer of the gallium nitride-based semiconductor layer 106 is prepared by the sputtering method. It is possible to reduce the resistance of the drain electrode and use it as a power transistor, by using the auxiliary electrode layer 110 in contact with the conductive alignment layer 104.

It is possible to apply the configuration of the gallium nitride semiconductor layer 106 shown in this embodiment to the configurations shown in the first through the eighth embodiments. It is possible for the gallium nitride-based semiconductor layer 106 to have various stacking structures as shown in FIG. 12A and FIG. 12B, and FIG. 13, and to configure a device according to the application.

### Tenth Embodiment

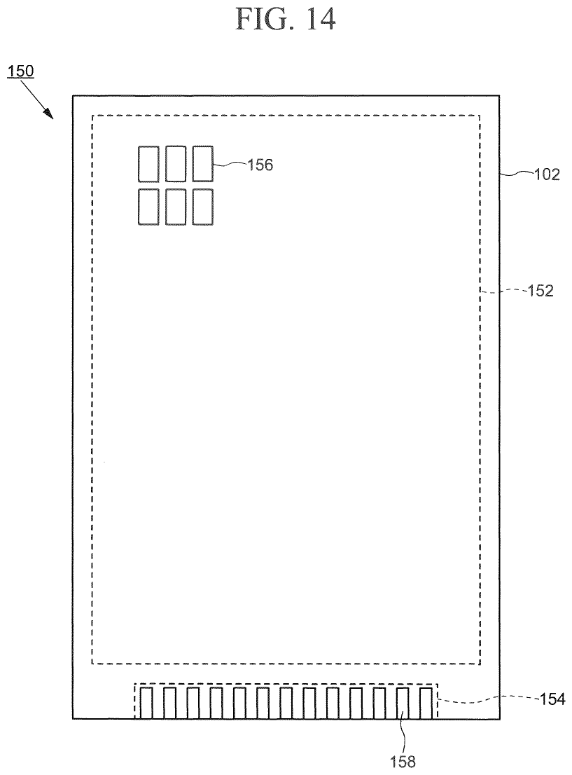

FIG. 14 is a schematic illustration of the configuration of a light emitting device 150 according to an embodiment of the present invention. The light emitting device 150 includes a pixel part 152 and a terminal part 154 formed on an amorphous substrate 102. The pixel part 152 is formed in a central portion of the amorphous substrate 102, and the terminal part 154 is formed at an edge of the amorphous substrate 102. The pixel part 152 includes a plurality of pixels 156 arranged in a matrix. Each of the plurality of pixels 156 is arranged with a light emitting device having the structure shown in the first embodiment to the sixth embodiment. The terminal part 154 includes a plurality of terminals 158. A power supply line is connected to each of the plurality of terminals 158 to apply voltage (supply current) to the light emitting devices in the pixels 156. Although details are not shown in the figure, a transistor may be arranged in the pixel 156, and the transistor may control the light emission of the light emitting device.

The first through tenth embodiments described above as embodiments of the present invention may be combined as appropriate, as long as they do not contradict each other. Also, based on each embodiment, any addition, deletion, or design change of configuration elements, or any addition or omission of processes, or any change of conditions made by a person skilled in the art as appropriate, are also included in the scope of the present invention as long as they have the gist of the invention.

Any other advantageous effects different from the advantageous effects resulting from the above-described embodiments, which are obvious from the description herein or which can be easily foreseen by those skilled in the art, are obviously to be understood as resulting from the present invention.

What is claimed is:

1. A gallium nitride-based semiconductor device, comprising:
an amorphous substrate;
a conductive alignment layer on the amorphous substrate;
a gallium nitride-based semiconductor layer on the conductive alignment layer; and
an auxiliary electrode layer in contact with the conductive alignment layer.

2. The gallium nitride-based semiconductor device according to claim 1, wherein the auxiliary electrode layer is arranged around a periphery portion of the conductive alignment layer.

3. The gallium nitride-based semiconductor device according to claim 2, wherein the auxiliary electrode layer is in contact with a side surface of the conductive alignment layer and an upper surface of the periphery portion of the conductive alignment layer, an outer periphery of a lower surface of the gallium nitride-based semiconductor layer is in contact with the auxiliary electrode layer, and an inner periphery of the lower surface of the gallium nitride-based semiconductor layer is in contact with the conductive alignment layer.

4. The gallium nitride-based semiconductor device according to claim 2, wherein the auxiliary electrode layer is in contact with a lower surface of the conductive alignment layer.

5. The gallium nitride-based semiconductor device according to claim 2, wherein the auxiliary electrode layer is in contact with a side surface of the conductive alignment layer and a part of a side surface of the gallium nitride-based semiconductor layer.

6. The gallium nitride-based semiconductor device according to claim 2, wherein the auxiliary electrode layer is in contact with an entire surface of a lower surface of the conductive alignment layer.

7. The gallium nitride-based semiconductor device according to claim 2, wherein the auxiliary electrode layer is arranged on a top surface or a bottom surface of the conductive alignment layer and has a lattice, stripe, or mesh pattern.

8. The gallium nitride-based semiconductor device according to claim 1, further comprising a plurality of stacked bodies having the conductive alignment layer and the gallium nitride-based semiconductor layer stacked on the conductive alignment layer;
wherein the plurality of stacked bodies is spaced apart on the amorphous substrate, and the auxiliary electrode layer connects the plurality of stacked bodies.

9. The gallium nitride-based semiconductor device according to claim 1, wherein the conductive alignment layer is continuously arranged on the amorphous substrate,
the gallium nitride-based semiconductor layer comprises a plurality of gallium nitride semiconductor layers, and the plurality of gallium nitride-based semiconductor layers arranged spaced apart on the conductive alignment layer, and
the auxiliary electrode layer is in contact with the conductive alignment layer and between regions where the plurality of gallium nitride-based semiconductor layers is arranged spaced apart.

10. The gallium nitride-based semiconductor device according to claim 1, wherein the amorphous substrate is a glass substrate.

11. The gallium nitride-based semiconductor device according to claim 1, wherein the conductive alignment layer is a c-axis aligned metal or metal oxide film.

12. The gallium nitride-based semiconductor device according to claim 11, wherein the conductive alignment layer is a metal film containing at least one element selected from titanium (Ti), aluminum (AI), silver (Ag), nickel (Ni), copper (Cu), strontium (Sr), rhodium (Rh), palladium (Pd), iridium (Ir), platinum (Pt), and gold (Au), or a metal oxide film containing any one of zinc oxide (ZnO) and titanium dioxide (TiO₂).

13. The gallium nitride-based semiconductor device according to claim 1, further comprising an upper electrode layer on top of the gallium nitride-based semiconductor layer.

14. The gallium nitride-based semiconductor device according to claim 1, wherein the gallium nitride-based semiconductor layer contains a plurality of gallium nitride layers of different conductive types.
